(19) United States
(12) Patent Application Publication
(10) Pub. No.: US 2007/0069798 A1
(43) Pub. Date: Mar. 29, 2007

(54) Switch circuit for high-frequency-signal switching

(75) Inventor: Keiji Kusachi, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/527,424

(22) Filed: Sep. 27, 2006

(30) Foreign Application Priority Data
Sep. 28, 2005 (JP) 2005-281673

(51) Int. Cl. H03K 17/687

(52) U.S. Cl. 327/430

(57) ABSTRACT

A switch circuit includes first and second input/output terminals; first depletion-mode transistors serially-connected between first and second nodes; second depletion-mode transistors serially-connected between third and fourth nodes; a common terminal connected to a connection node; a bias circuit feeding a first bias voltage to gates of the first depletion-mode transistors, and feeding a second bias voltage to selected one of the third and fourth nodes; and a switch control terminal receiving a control voltage. The first node is connected to the first input/output terminal, while the third node is connected to the second input/output terminal. The second and fourth nodes are connected to the connection node. A capacitor element is connected between the connection node and selected one of the second and fourth nodes. The switch control terminal is connected to gates of the second depletion-mode transistors, and to selected one of the first and second nodes.

### BACKGROUND OF THE INVENTION

1. Field of the Invention

The present invention relates to a semiconductor switch circuit device, particularly to a semiconductor switch circuit device for switching high frequency signals.

2. Description of the Related Art

Semiconductor switch circuits used for switching transmission and reception of high frequency signals in the antenna front end of cellular phones are required to provide enhanced switching performance, from the background of the remarkable advance in the integration degree and function of cellular phones. One commonly known circuit for switching transmission and reception is the SPDT (Single Pole Dual Throw) switch circuit.

In general, an SPDT switch circuit is controlled with a pair of complementary control signals; however, the use of complementary control signals is undesirable from the viewpoint of control system simplicity. It would be advantageous if an SPDT switch circuit is controlled with a single control signal.

FIG. 1 is a circuit diagram of a conventional switch circuit controlled with a single control signal, which is disclosed in Japanese Laid Open Patent Application No. JP-A 2005-5857. The switch circuit device shown in FIG. 1 includes a common terminal IN, a pair of input/output terminals OUT1 and OUT2, a switch module F1 provided between the common terminal IN and the input/output terminal OUT1, and a switch module F2 provided between the common terminal IN and the input/output terminal OUT2. The switch module F1 includes three serially-connected FETs (field effect transistors) 1-1, 1-2 and 1-3. Correspondingly, the switch module F2 includes three serially-connected FETs 2-1, 2-2 and 2-3.

Depletion-mode FETs, which have a negative threshold voltage Vth, are used as the FET 1-1 to 1-3 and 2-1 to 2-3. The threshold voltage Vth of the field effect transistors 1-1 to 1-3 and 2-1 to 2-3 is typically about −0.5 V. One important feature of a depletion-mode FET is normally-on characteristics as shown in FIG. 2; even when the gate-source voltage is zero, a channel is formed below the gate, and thereby a drain current is allowed to flow across the depletion-mode FET. The channel is narrowed by applying a negative bias to the gate, and the depletion-mode FET is turned off when the gate-source voltage is decreased down to or below the threshold voltage Vth. In the following, it is assumed that the FETs 1-1 to 1-3 and 2-1 to 2-3 have a threshold voltage Vth of −0.5 V; the FETs 1-1 to 1-3 and 2-1 to 2-3 are turned off with the gate-source voltage lower than −0.5 V, while being turned with the gate source voltage higher than −0.5 V. It should be noted that the FETs 1-1 to 1-3 and 2-1 to 2-3 are tuned on, when the gate-source voltage Vgs is 0 V.

Referring back to FIG. 1, the gates of the FET 1-1, 1-2 and 1-3 are connected to a control terminal CTL through resistors Ra1, Ra2 and Ra3, respectively, while the gates of the FET 2-1, 2-2 and 2-3 are connected to ground through resistors Rb1, Rb2 and Rb3, respectively. The switch module F1 and the switch module F2 are isolated from each other by a capacitor C with respect to the dc signal component.

An input/output end of the switch module F1 connected to the input/output terminal OUT1 is connected to a power supply terminal V through a resistor Rc. An input/output end of the switch module F2 connected to the input/output terminal OUT2 is connected to the control terminal CTL via a resistor Rd.

The switch circuit shown in FIG. 1 operates as follows: A voltage of 2.8 V is fed to the power supply terminal VDD, and a control voltage of 2.8 or 0 V is applied to the control terminal CTL so as to control the switch circuit.

When the control terminal CTL receives a control voltage of 2.8 V, the voltage levels on the gates of the FETs 1-1, 1-2 and 1-3 in the switch module F1 are also 2.8 V. The gate-source voltage Vgs of the FET 1-3 is set to 0 V, because the source (or the drain) of the FET 1-3 is connected to the power supply terminal V, and set to 2.8 V. Therefore, the FET 1-3 is placed into the on-state. Correspondingly, a voltage of 2.8 V is applied to the source (or the drain) of the FET 1-2, and the FET 1-2 is also placed into the on-state the on state. Finally, the FET. 1-1 is also placed into the on-state in the same manner. Accordingly, the common input/output terminal IN is electrically connected with the input/output terminal OUT1.

Meanwhile, the voltage of the connection node of the FET 2-3 and the input/output terminal OUT2 is 2.8 V, because a voltage of 2.8 volts is applied to. The gates of the FET 2-1, FET 2-2 and FET 2-3 are electrically connected to ground through the resistors Rb1, Rb2 and Rb3, respectively, and therefore the gate-source voltage Vgs of the FETs 2-1, 2-2 and 2-3 are set to −2.8 V. This places the FET 2-1, FET 2-2 and FET 2-3 into the off-state, because the gate source voltage Vgs is sufficiently lower than the threshold voltage Vth of the FETs 2-1, 2-2 and 2-3. the common input terminal IN is electrically isolated from the input/output terminal OUT2.

When the control voltage applied to the control terminal CTL is 0 V, on the other hand, the gates of the FET 1-1, FET 1-2 and FET 1-3 are set to 0 V. This results in that the gate source voltage Vgs of the FETs 1-1, 1-2 and 1-3 is −2.8 V, because the sources (or the drain) of the FETs 1-1, 1-2 and 1-3 are connected to the power supply terminal VDD and set to 2.8 V. Accordingly, the FETs 1-1, 1-2 and 1-3 are placed into the off-state, and the common input/output terminal IN is electrically isolated from the input/output terminal OUT1.

Meanwhile, the voltage of the connection node between the switch module F2 and the input/output terminal OUT2 is set to 0 V, because the control terminal CTL receives a voltage of 0 V. The gates of the FETs 2-1, 2-2, and 2-3 are connected to ground through the resistors Rb1, Rb2 and Rb3, and thereby the gate source voltage Vgs of the FETs 2-1, 2-2 and 2-3 is set to 0 V. Therefore, the FETs 2-1, 2-2 and 2-3 are placed into the on-state, and the common input/output terminal IN is electrically connected with the input/output terminal OUT2.

As thus described, the switch circuit is designed to switch the switch modules F1 and F2 in response to the switching of the single control voltage fed to the control terminal CTL between 2.8 V and 0 V.

A similar switch circuit configuration is disclosed in Japanese Laid Open Patent Application No. JP-A 2005-5859, in which a control terminal is realized by a single terminal.

One problem is that the switch circuit shown in FIG. 1 often suffers from non-linearity when dealing with a high power signal. The SPDT switching circuit is required to achieve. input-output linearity. Additionally, an SPDT switch circuit is desired to provide high handling power. In a GSM (Global System for Mobile communication), which is one of the most widely used cellular phone systems, for example, an output power from an antenna is increased up to about 4 watts. Therefore, the SPDP switch circuit in the GSM is required to deal with such a high power output signal. However, the switch circuit shown in FIG. 1 does not satisfy such requirements.

This would be understood from FIG. 2, which shows an example of three-terminal characteristics of a depletion-mode FET with a gate width of 2400 μm and a threshold voltage Vth of −0.5 V. When an input signal with a power of 4 watts is fed to the SPDP switch circuit including such-designed FETs, a drain current of 200 mA or more is generated across the FETs. In the switch circuit shown in FIG. 1, the FETs are turned on with the gate-source voltage Vgs of 0 V. This undesirably-causes the FETs to operate in the non-linear region (the saturated region) as shown in FIG. 2. One approach for avoiding this problem may be to increase the gate width of the FETs; however, the increase in the gate width deteriorates the isolation characteristics, which is important for the SPDT switch circuit.

### SUMMARY OF THE INVENTION

In an aspect of the present invention, A switch circuit is composed of first and second input/output terminals; first depletion-mode transistors serially-connected between first and second nodes; second depletion-mode transistors serially-connected between third and fourth nodes; a common terminal connected to a connection node; a bias circuit feeding a first bias voltage to gates of the first depletion-mode transistors, and feeding a second bias voltage to selected one of the third and fourth nodes; and a switch control terminal receiving a control voltage. The first: node is connected to the first input/output terminal, while the third node is connected to the second input/output terminal. The second and fourth nodes are connected to the connection node. A capacitor element is connected between the connection node and selected one of the second and fourth nodes. The switch control terminal is connected to gates of the second depletion-mode transistors, and to selected one of the first and second nodes. The control voltage has a voltage level selected out of a higher power supply voltage and a lower power supply voltage. The first bias voltage is higher than the lower power supply voltage, and the second bias voltage is higher than the first bias voltage and lower than the higher power supply voltage.

The above-described switch circuit, which is controllable with the single control voltage, effectively avoids the first and second depletion-mode FETs being operated in the non-linear region, because of the first and second bias voltages thus generated. This effectively improves the input/output linearity of the switch circuit for a high power input signal.

### BRIEF DESCRIPTION OF THE DRAWINGS

The above and other advantages and features of the present invention will be more apparent from the following. description taken in conjunction with the accompanied drawings, in which:

FIG. 1 is a circuit diagram showing a circuit configuration of a conventional switch circuit;

FIG. 2 is a graph showing three-terminal characteristics of a depletion-mode FET;

FIG. 3 is a circuit diagram showing a circuit configuration of a switch circuit in a first embodiment;

FIG. 4 is a circuit diagram showing a modified circuit configuration of a switch circuit in the first embodiment; and

FIG. 5 is a circuit diagram showing a circuit configuration of a switch circuit in a second embodiment.

### DESCRIPTION OF THE PREFERRED EMBODMIENTS

The invention will be now described herein with reference to illustrative embodiments. Those skilled in the art would recognize that many alternative embodiments can be accomplished using the teachings of the present invention and that the invention is not limited to the embodiments illustrated for explanatory purposed.

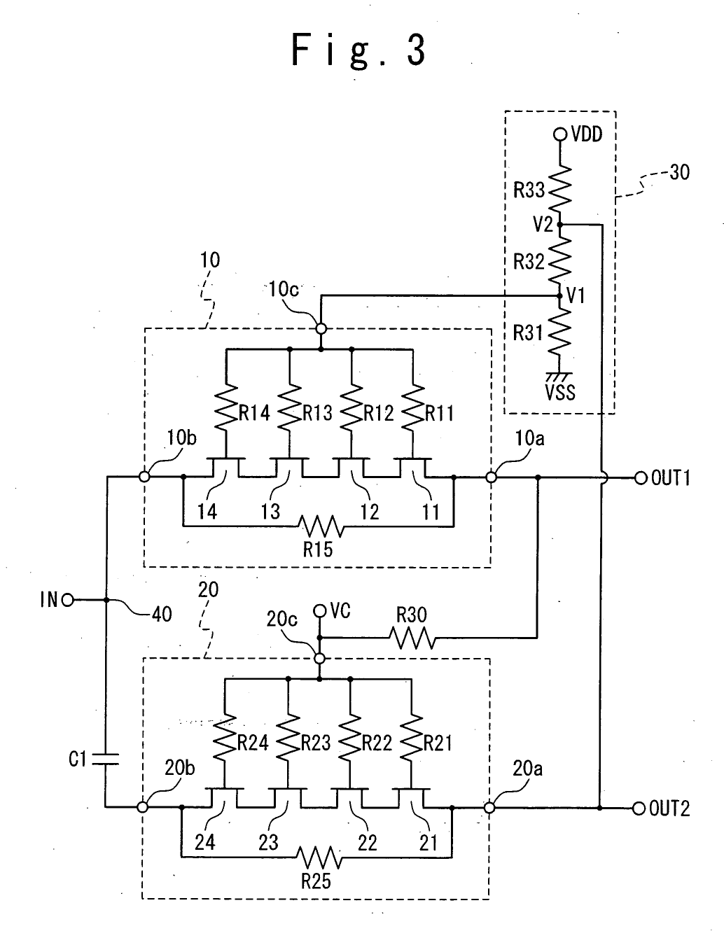

FIG. 3 is a circuit diagram showing a circuit configuration of a semiconductor switch circuit in a first embodiment of the present invention. The switch circuit includes a common terminal IN, input/output terminals OUT1 and OUT2. The switch circuit shown in FIG. 3 is designed to transmit a high frequency signal (typically an RF (radio frequency) signal) between the common terminal IN and selected one of the input/output terminals OUT1 and OUT2.

Specifically, the switch circuit is provided with a pair of switch modules 10 and 20, a bias circuit 30, a resistor R30, and a capacitor C1. The switch module 10 has a first input/output node 10a connected to the input/output terminal OUT1, and a second input/output node 10b connected to a connection node 40, which is connected to the common terminal IN. Correspondingly, the switch module 20 has a first input/output node 20a connected to the input/output terminal OUT2, and a second input/output node 20b connected to the connection node 40. The capacitance element C1 is interposed between the input/output node 20b of the switch module 20 and the connection node 40 so as to cut off the DC bias voltages between the switch modules 10 and 20.

The switch module 10 is composed of depletion-mode FETs 11 to 14, and resistors R11 to R15. The FETs 11 to 14 are serially-connected between the first and second input/output nodes 10a and 10b within the switch module 10. The resistor R15 is connected between first and second input/output nodes 10a and 10b in parallel to the serially-connected FETs 11 to 14. The gates of the FETs 11 to 14 are connected to a control node 10c of the switch module 10 through the resistors R11 to R14, respectively. The resistors R11 to R14 are used to avoid leakage of the high frequency signal from the FETs 11 to 14 to the control node 10c.

Correspondingly, the switch module 20 includes depletion-mode FETs 21 to 24 and resistors R21 to R25. The FETs 21 to 24 are serially-connected between first and second input/output nodes 20a and 20b within the switch module 20. The resistor R25 is connected between first and second input/output nodes 20a and 20b in parallel to the serially-connected FETs 21 to 24. The gates of the FETs 21 to 24 are connected to a control node 20c of the switch module 20 through the resistors R21 to R24, respectively. The resistors R21 to R24 are used to avoid leakage of the high frequency signal from the FETs 21 to 24 to the control node 20c.

A switch control terminal VC is connected to the control node 20c of the switch module 20, and also connected to the first input/output node 10a of the switch module 10 through the resistor R30. The resistor R30 avoids leakage of the high frequency signal to the switch control terminal VC from the first input/output node 10a of the switch module 10.

The bias circuit 30 is composed of resistors R31, R32 and R33 that are serially-connected between power supply terminals VDD and VSS. The power supply terminal VDD is fed with a higher power supply voltage Vdd, while the power supply terminal VSS is fed with a lower power supply voltage Vss (which is typically a ground level voltage). The bias circuit 30 generates and provides bias voltages V1 and V2 for the switch modules 10 and 20 through voltage dividing. The bias voltage V1 is fed to the control node 10c of the switch module 10, and the bias voltage V2 is fed to the first input/output node 20a of the switch module 20. The bias voltage V1 is generated on the connection node between the resistors R31 and R32, and the bias voltage V2 is generated on the connection node between the resistors R32 and R33. The bias voltages V1 and V2 are represented as follows:
V1=Vss+(Vdd−Vss)×r31/(r31+r32+r33), and
V2=Vss+(Vdd−Vss)×(r31+r32)/(r31+r32+r33),
where r31, r32 and r33 are resistances of the resistors R31, R32 and R33, respectively. It should be noted that the bias voltages V1 is higher than the lower power supply voltage Vss, and the bias voltage V2 is higher than the bias voltage V1 and lower than the higher power supply voltage Vdd.

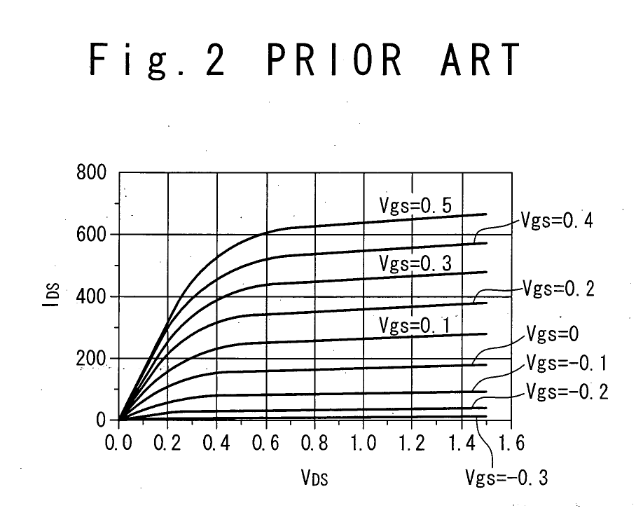

A description is made of an exemplary operation of the switch circuit shown in FIG. 3, assuming that the FETs 11 to 14 and 21 to 24 are depletion-mode FETs with a gate width of 240 μm and a threshold voltage Vth of −0.5 V, having a three-terminal characteristics shown in FIG. 2. It is also assumed that the lower power supply voltage Vss fed to the power supply terminal VSS is 0 V, and the higher power supply voltage Vdd fed to the power supply terminal VDD is 2.8 V. The switch control terminal VC receives a control voltage having a voltage level of 2.8 V or 0 V. It is further assumed that resistances of the resistors R31, R32 and R33 within the bias circuit 30 are 9 kΩ, 45 kΩ and 9 kΩ, respectively.

In this case, the bias voltage V1 is 0.4 V, and the bias voltage V2 is 2.4 V. This results in that the gate voltage of the FETs 11 to 14, which are fed with the bias voltage V1, is 0.4 V, and the voltage level of the first input/output node 20a, which is fed with the bias voltage V2, is 2.4 V.

When the control voltage received by the switch control terminal VC is 2.8 V, the first input/output node 10a of the switch module 10 is pulled up to 2.8 V. Therefore, the gate source voltage Vgs of the FETs 11 to 14 is set to −2.4 V, since the gate voltage of the FETs 11 to 14 is 0.4 V. The generated gate-source voltage Vgs is sufficiently lower than a threshold voltage Vth of −0.5 V, and the FETs 11 to 14 are placed into the off-state with a sufficient margin.

Meanwhile, the control voltage received by the switch control terminal VC is distributed to the respective gates of the FETs 21 to 24 in the switch module 20, thereby the gates of the FETs 21 to 24 are pulled up to 2.8 V. This results in that the gate-source voltage Vgs of the FETs 21 to 24 is 0.4 V, since the voltage level of the first input/output node 20a of the switch module 20 is 2.4 volts.

Accordingly, the FETs 21 to 24 are placed into the on-state.

It should be noted that the FETs 21 to 24 operate in the linear region when the gate-source voltage Vgs thereof is 0.4 V and the drain current Ids thereof is 200 mA, as is understood from FIG. 2. Even when an input signal with a power of 4 watts is input to the switch module 20 and thereby the drain current of 200 mA is generated, the FETs 21 to 24 operate in the linear region with a sufficient margin.

When the control voltage received by the switch control terminal VC is 0 V, on the other hand, the first input/output node 10a of the switch module 10 is pulled down to 0 V. This results in that the gate-source voltage Vgs of the FETs 11 to 14 are set to 0.4 V, since the bias voltage V1 received by the gates of the FETs 11 to 14 is 0.4 V. Accordingly, the FETs 11 to 14 are placed into the on-state.

Meanwhile, the gate voltage of the FETs 21 to 24 is pulled down to 0 V. This results in that the gate-source voltage Vgs of the FETs 21 to 24 is −2.4 volts, since the first input/output node 20a of the switch module 20 is pulled up to 2.4 V. Accordingly, the FETs 21 to 24 are placed into the off-state.

The states of the FETs 11 to 14 and 21 to 24 with the control voltage set to 0 V are complementary to those with the control voltage set 2.8 V. It would be therefore understood that the FETs 11 to 14 operate in the linear region with a sufficient margin, and the FETs 21 to 24 are placed into the off-state with a sufficient margin, when the control voltage fed to the switch control terminal VC is set to 0 V.

As thus described, the switch circuit in this embodiment achieves the control of the switch modules 10 and 20 with a single control voltage, while the FETs placed into on-state operate in the linear region with a sufficient margin.

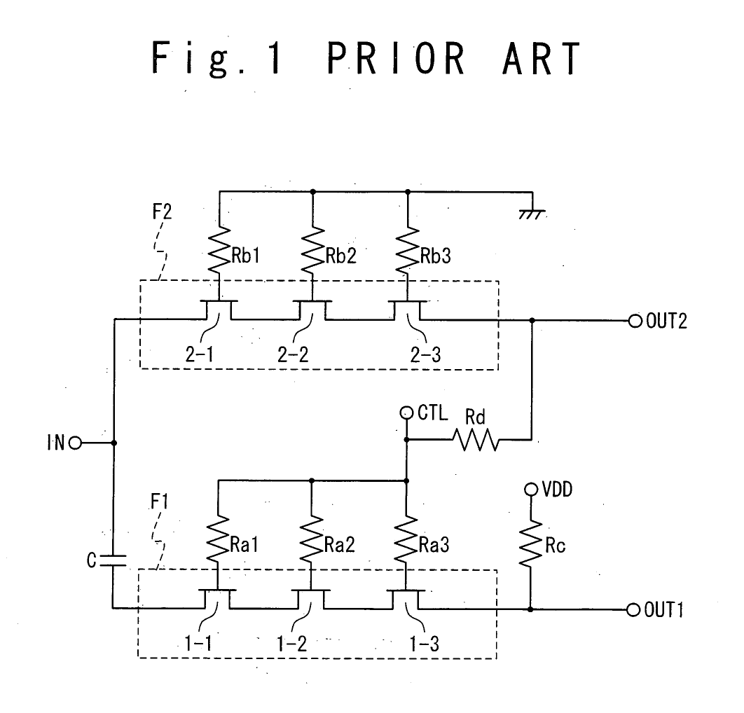

It should be noted that the bias circuit 30, which generates the bias voltages V1 and V2 through voltage dividing, has an additional effect to reduce the fluctuation of the bias voltages fed to the FETs. In the conventional switch circuit shown in FIG. 1, the fluctuation of 0.2 V in the higher power supply voltage Vdd (typically 2.8 V) results in the fluctuation of ±0.2 V in the bias voltage fed to the FETs. On the contrary, the switch circuit in this embodiment, the fluctuation in the bias voltage V2 fed to the FETs 21 to 24 is reduced to ±0.17 V for the fluctuation of ±0.2 V in the higher power supply voltage Vdd under the above-described circuit constants (such as the resistances), since the fluctuation in the bias voltage V2 is attenuated by (r31+r32)/(r31+r32+r33) in the bias circuit 30. Furthermore, the fluctuation in the bias voltage V1 fed to the gates of the FETs 11 to 14 in the switch module 10 is reduced to ±0.03 V, since the fluctuation in the bias voltage V1 is attenuated by r31/(r31+r32+r33) in the bias circuit 30. Accordingly, the switch circuit in this embodiment is superior in the tolerance to the power supply voltage fluctuation.

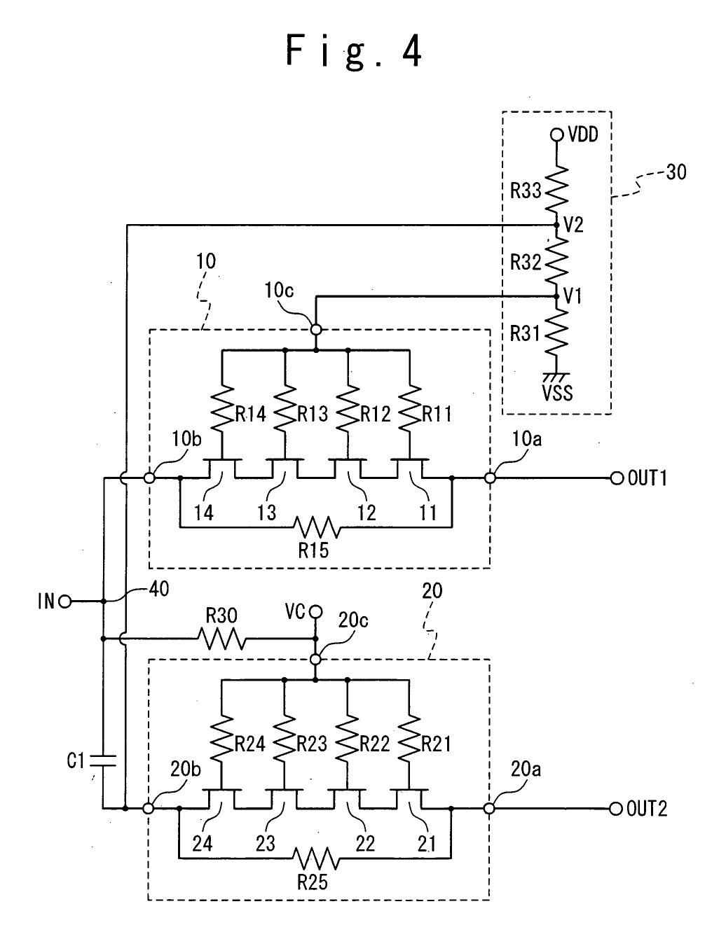

FIG. 4 is a circuit diagram showing a modified configuration of the switch circuit in the first embodiment. The biasing circuitry for the FETs 11 to 14 and 21 to 24 may be modified. Specifically, the switch control terminal VC may be connected with the second input/output node 10b of the switch module 10 in place of the first input/output node 10a. Alternatively or additionally, the bias voltage V2 may be fed to the second input/output node 20b of the switch module 20 in place of the first input/output node 20a. It should be noted that the switch control terminal VC may be connected with the second input/output node 10b with the bias voltage V2 fed to the second input/output node 10b. It should be also noted that the bias voltage V2 may be fed to the second input/output node 20b with the switch control terminal VC connected to the first input/output node 10a.

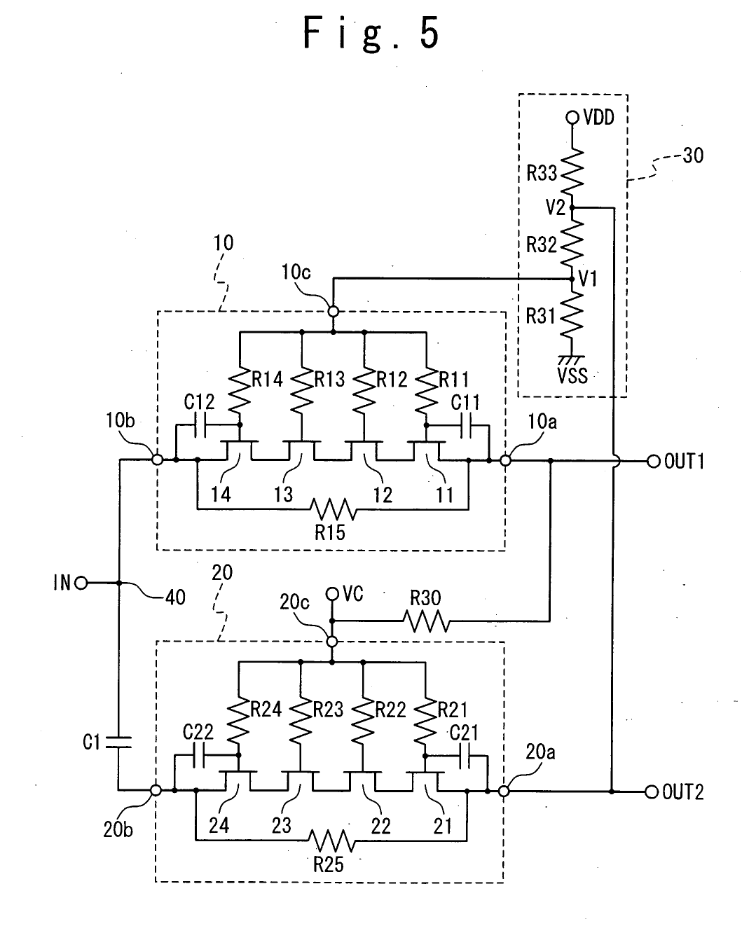

FIG. 5 is a circuit diagram showing the configuration of the switch circuit in a second embodiment of the present invention. In the second embodiment, the switch circuit is designed to include feed through capacitors, and thereby to provide the bias voltages to the FETs so that the FETs are placed into the off-state with an improved margin.

Specifically, the switch module 10 additionally includes a pair of capacitors C11 and C12. The capacitor C11 is connected between the first input/output node 10a and the gate of the FET 11, which is positioned at one end of the serially-connected FETS 11 to 14. The capacitor C12 is, on the other hand, connected between the second input/output node 10b and the gate of the FET 14, which is positioned at the other end of the serially-connected FETS 11 to 14. Correspondingly, the switch module 20 additionally includes a pair of capacitors C21 and C22. The capacitor C21 is connected between the first input/output node 20a and the gate of the FET 21, and the capacitor C22 is connected between the second input/output node 20b and the gate of the FET 24.

The capacitors C11, C12, C21, and C22 have such capacitances that the impedances thereof are sufficiently low with respect to the RF signal which is to be transmitted between the common terminal IN and the input/output terminal OUT1 or OUT2. The capacitors C11, C12, C21, and C22 stabilize the gate-source voltages Vgs of the FETs connected thereto, regardless of the amplitude of the RF input signal. Additionally, the FET 11 or the FET 21 is turned off when the voltage level of the RF input signal is positive, while the FET 14 or 24 is turned off when the voltage level of the RF input signal is negative. Therefore, selected one of the switch module 10 or 20 is turned off regardless of the voltage level of the RF input signal. As thus described, the feed through capacitors C11, C12, C21, and C22 allows the FETs to be completely turned off for high power input, and thereby improves the handling power of the switch circuit.

It is apparent that the present invention is not limited to the above-described embodiments, which may be modified and changed without departing from the scope of the invention.

For example, although FIGS. 3 to 5 illustrates the configurations in which the capacitor C1 is connected between the connection node 40 and the second input/output node 20b of the switch module 20, the capacitor C1 may be connected between the connection node 40 and the second input/output node 10b of the switch module 10. This is based on the fact that the capacitance element C1 is used to cut off the DC bias voltages between the switch module 10 and the switch module 20.

What is claimed is:

1. A switch circuit comprising:
first and second input/output terminals;
first depletion-mode transistors serially-connected between first and second nodes, said first node being connected to said first input/output terminal, and said second node being connected to a connection node;
second depletion-mode transistors serially-connected between third and fourth nodes, said third node being connected to said second input/output terminal, and said fourth node being connected to said connection node;
a capacitor element connected between said connection node and selected one of said second and fourth nodes;
a common terminal connected to said connection node;
a bias circuit feeding a first bias voltage to gates of said first depletion-mode transistors, and feeding a second bias voltage to selected one of said third and fourth nodes; and
a switch control terminal receiving a control voltage, said switch control terminal being connected to gates of said second depletion-mode transistors, and to selected one of said first and second nodes,
wherein said control voltage has a voltage level selected out of a higher power supply voltage and a lower power supply voltage,
wherein said first bias voltage is higher than said lower power supply voltage, and
wherein said second bias voltage is higher than said first bias voltage and lower than said higher power supply voltage.

2. The switch circuit according to claim 1, wherein the bias circuit includes:
first to third resistor elements serially-connected between first and second power supply terminals fed with said lower and higher power supply voltages, respectively, and
wherein said first bias voltage is generated on a fifth node on which said first and second resistor elements-are connected, and
wherein said second bias voltage is generated on a sixth node on which said second and third resistor elements are connected.

3. The switch circuit according to claim 1, further comprising:
a first resistor element connected between said first and second nodes; and
a second resistor element connected between said third and fourth nodes.

4. The switch circuit according to claim 1, further comprising:
a third resistor element connected between said switch control terminal and said selected one of said first and second nodes.

5. The switch circuit according to claim 2, wherein each of said gates of said first depletion-mode transistors is connected to said fifth node through a resistor element, and
wherein each of said gates of said second depletion-mode transistors is connected to said switch control terminal thorough a resistor element.

6. The switch circuit according to claim 1, further comprising:
a first feed through capacitor connected between said first node and a gate of one of said first depletion mode transistors, said one of said first depletion mode transistors having a source/drain connected to said first node;
a second feed through capacitor connected between said second node and a gate of another of said first depletion mode transistors, said another of said first depletion mode transistors having a source/drain connected to said second node;
a third feed through capacitor connected between said third node and a gate of one of said second depletion mode transistors, said one of said second depletion mode transistors having a source/drain connected to said third node; and
a fourth feed through capacitor connected between said fourth node and a gate of another of said second depletion mode transistors, said another of said second depletion mode transistors having a source/drain connected to said fourth node.
